(19) United States
(12) Patent Application Publication
(10) Pub. No.: US 2006/0147816 A1
(43) Pub. Date: Jul. 6, 2006

(54) Multi-transmission phase mask and method for manufacturing the same

(75) Inventor: Chan Ha Park, Suwon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Icheon-shi (KR)

(21) Appl. No.: 11/073,183

(22) Filed: Mar. 3, 2005

(30) Foreign Application Priority Data
Dec. 30, 2004 (KR) 2004-117300

(51) Int. Cl. G03C 5/00; G03F 1/00

(52) U.S. Cl. 430/5; 430/311; 430/312; 430/313

(57) ABSTRACT

A multi-transmission phase mask, and a method of manufacturing a multi-transmission phase mask are disclosed. The method comprises the steps of primarily patterning a light shielding layer after forming the light shielding layer on a light transmissive substrate, forming a plurality of pattern regions of a semiconductor by etching the light transmissive substrate to a predetermined depth using the primarily patterned light shielding layer, and secondarily patterning the light shielding layer and forming a phase shift region between the adjacent pattern regions of the semiconductor such that a predetermined portion of a surface of the light transmissive substrate is exposed to the outside between the adjacent pattern regions of the semiconductor. Each of the pattern regions provides a phase delay of 180° while a gap between the pattern regions provides a phase delay of 0°, thereby realizing a minute pattern and a critical dimension of the pattern with high precision.

### CROSS-REFERENCES TO RELATED APPLICATIONS

This application claims the benefit of Korean Patent Application No. 2004-117300 filed Dec. 30, 2004, the entire contents of which are hereby incorporated by reference for all purposes.

### FIELD OF THE INVENTION

The present invention relates to a photolithography technology, and more particularly to a multi-transmission phase mask, designed to prevent deterioration of the minute pattern of a semiconductor, thereby realizing a critical dimension with high precision, and a method for manufacturing the same.

### BACKGROUND OF THE INVENTION

As with a dynamic random memory (DRAM) or a flash memory, if a predetermined minute pattern of a semiconductor is repeated with an identical shape on a photo-mask, an optical proximity effect occurs wherein a pattern design of the photo-mask is not identically projected onto a wafer, causing a pattern on the wafer to differ from that of the photo-mask, due to lens aberration caused by limitation in the resolution of an exposure apparatus. For example, during an exposure process for a mask having a hole pattern, such as a storage node contact and so forth, the optical proximity effect occurs due to the limitation in resolution and a minute gap between pattern units, so that an image of the hole pattern exposed on the wafer has not a circular shape but a distorted shape.

In order to compensate for such an optical proximity effect on the resulting shape of the pattern on the wafer, although a method of modifying the shape of the pattern of the mask or a method of adding an assistant pattern to the pattern of the mask has been suggested in the prior art, there still remains a difficulty in realizing a critical dimension of the pattern with high precision.

For the purpose of solving the problems as described above, a method is suggested, in which the critical dimension of a minute pattern, such as the storage node contact and so forth, is realized by use of a multi-transmission phase mask (MTPM) that allows light for exposure to be transmitted to certain pattern units and to a gap between the pattern units with different phases.

FIGS. 1a to 1c show one example of a conventional multi-transmission phase mask, in which FIG. 1b is a vertical cross-sectional view taken along line A-A′ of FIG. 1a, and FIG. 1c is a vertical cross-sectional view taken along line B-B′ of FIG. 1a.

One example of the conventional multi-transmission phase mask comprises a light shielding layer 12 formed on a light transmissive substrate 10 so as to prevent light from being transmitted therethrough and defining storage node contacts and a gap between the contacts, and a phase shift region 14 formed by etching the light transmissive substrate 10 to a predetermined depth in a space in a row direction between the storage node contacts. At this time, each of the storage node contacts, between which the surface of the light transmissive substrate 10 is exposed to the outside, serves to provide a phase delay of 0° for transmitted light. Meanwhile, the phase shift region 14 formed by etching the light transmissive substrate 10 to the predetermined depth through the light shielding layer 12 and defining the distance of the row between the storage node contacts serves to provide a phase delay of 180° for the transmitted light. Accordingly, the light transmissive substrate 10 in the storage node contacts provides a phase delay of 0° for the transmitted light, whereas the phase shift region 14 formed on the gap in the row direction between the storage node contacts provides a phase delay of 0° for the transmitted light, whereby a phase difference of about 180° is generated between the light transmissive substrate 10 and the phase shift region 14, thereby compensating for the optical proximity effect between patterns of the mask.

FIGS. 2a to 2c show another example of a conventional multi-transmission phase mask, in which FIG. 2b is a vertical cross-sectional view taken along line A-A′ of FIG. 2a, and FIG. 2c is a vertical cross-sectional view taken along line B-B′ of FIG. 2a.

Another example of the conventional multi-transmission phase mask comprises a light shielding layer 12 formed on a light transmissive substrate 10 so as to prevent light from being transmitted therethrough and defining storage node contacts and a gap between the contacts, and a phase shift region 14 formed by etching the light transmissive substrate 10 to a predetermined depth in a space in the row direction between the storage node contacts. At this time, each of the storage node contacts, between which the surface of the light transmissive substrate 10, is exposed to the outside and serves to provide a phase delay of 0° for transmitted light. Meanwhile, the phase shift region 14 formed by etching the light transmissive substrate 10 to the predetermined depth through the light shielding layer 12 and defining the distance of the row between the storage node contacts serves to provide a phase delay of 180° for the transmitted light. Accordingly, a phase difference of about 180° is generated between the light transmissive substrate 10 in the storage node contacts and the phase shift region 14 formed on the gap in the row direction between the storage node contacts, thereby compensating for the optical proximity effect between patterns of the mask.

With regard to this, precise adjustment of an overlay between the pattern the multi-transmission phase mask providing the phase delay of 0° and the phase shift region 14, which is the gap between the patterns of the multi-transmission phase mask and provides the phase delay of 180°, ensures a higher critical dimension of the pattern.

That is, when a correct overlay of the pattern and the gap between the patterns, which generates a phase difference as shown in FIG. 3a, is provided, a desired profile of the pattern and a critical dimension of the pattern can be realized with high precision, whereas when an incorrect overlay of the pattern and the gap between pattern units is provided with deviation of about 20 nm as shown in FIG. 3b, a light shielding layer, such as a chrome film, is present in the pattern and the gap between the pattern units, thereby providing an unwanted critical dimension. Moreover, as shown in FIGS. 3c and 3d, in the case of the correct overlay of the pattern and the gap, which generate the phase difference, good optical intensity is obtained, whereas in the case of the incorrect overlay, the optical intensity is reduced, making it difficult to ensure the desired critical dimension of the pattern.

### SUMMARY OF THE INVENTION

The present invention has been made to solve the above problems, and it is an object of the present invention to provide a multi-transmission phase mask, which is provided with a light shielding layer and a phase shift region such that each pattern region provides a phase delay of 180° and a gap between the pattern regions provides a phase delay of 0°, thereby realizing a minute and repetitious pattern of a semiconductor, such as storage node contacts, and a critical dimension of the pattern with high precision.

It is another object of the present invention to provide a method of manufacturing a multi-transmission phase mask, comprising a primary patterning process for forming a plurality of pattern regions, each having a phase of 180°, and a secondary patterning process for forming a gap between the pattern regions, which has a phase of 0°, thereby realizing a minute and repetitious pattern of a semiconductor, such as storage node contacts, and a critical dimension of the pattern with high precision.

In accordance with an aspect of the present invention, the above and other objects can be accomplished by the provision of a multi-transmission phase mask used for an exposure apparatus, comprising: a light transmissive substrate of the mask; a light shielding layer formed on the light transmissive substrate so as to prevent light from being transmitted therethrough and defining a plurality of pattern regions of a semiconductor; and a phase shift region formed between the adjacent pattern regions such that a predetermined portion of a surface of the light transmissive substrate is exposed to the outside between the adjacent pattern regions, each region being formed by etching the light transmissive substrate to a predetermined depth through the light shielding layer.

In accordance with another aspect of the present invention, a method of manufacturing a mask used for an exposure apparatus is provided, which comprises the steps of: first patterning a light shielding layer after forming the light shielding layer on a light transmissive substrate; forming a plurality of pattern regions of a semiconductor by etching the light transmissive substrate to a predetermined depth through the primarily patterned light shielding layer; and secondarily patterning the light shielding layer and forming a phase shift region between the adjacent pattern regions of the semiconductor such that a predetermined portion of a surface of the light transmissive substrate is exposed to the outside between the adjacent pattern regions.

### BRIEF DESCRIPTION OF THE DRAWINGS

The foregoing and other objects and features of the present invention will be more clearly understood from the following detailed description taken in conjunction with the accompanying drawings, in which:

FIGS. 1a to 1c show one example of a conventional multi-transmission phase mask;

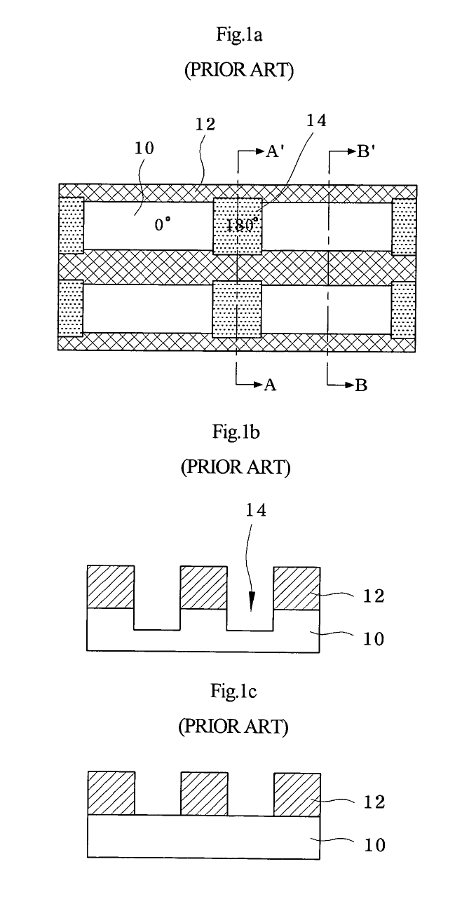

FIGS. 2a to 2c show another example of a conventional multi-transmission phase mask;

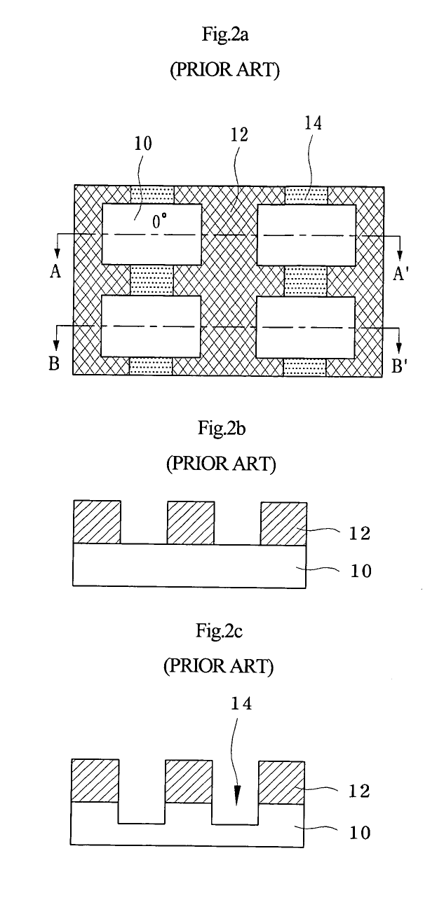

FIGS. 3a to 3d show the cases of correct and incorrect phase overlay of patterns and gaps between the patterns of the conventional multi-transmission phase mask, and graphs for comparing optical intensities in these cases;

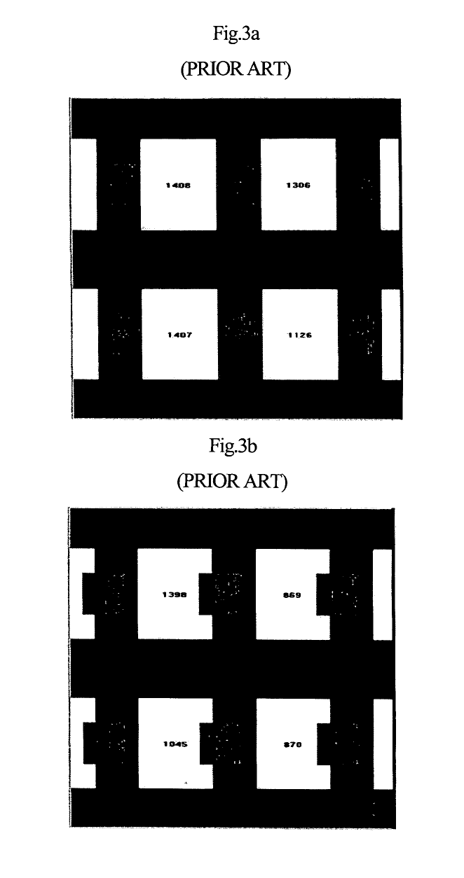

FIGS. 4a to 4c are a plan view, and vertical cross-sectional views respectively illustrating a multi-transmission phase mask in accordance with one preferred embodiment of the present invention;

FIGS. 5a to 5c are a plan view, and vertical cross-sectional views respectively illustrating a multi-transmission phase mask in accordance with another preferred embodiment of the present invention;

FIGS. 6a and 6b are diagrams illustrating a primary exposure process in a method of manufacturing a multi-transmission phase mask of the present invention;

FIGS. 7a to 7c are diagrams illustrating the primary etching process in the method of the present invention;

FIGS. 8a and 8b are diagrams illustrating a secondary exposure process in the method of the present invention;

FIGS. 9a to 9d are diagrams illustrating the secondary etching process in the method of the present invention;

FIG. 10 shows one example of a modified illumination system employed upon manufacturing the multi-transmission phase mask of the present invention; and

FIG. 11 shows a pattern of storage node contacts exposed on a wafer when an exposure process is conducted using the multi-transmission phase mask of the invention and the modified illumination system.

### DETAILED DESCRIPTION OF THE INVENTION

Preferred embodiments will now be described in detail with reference to the accompanying drawings.

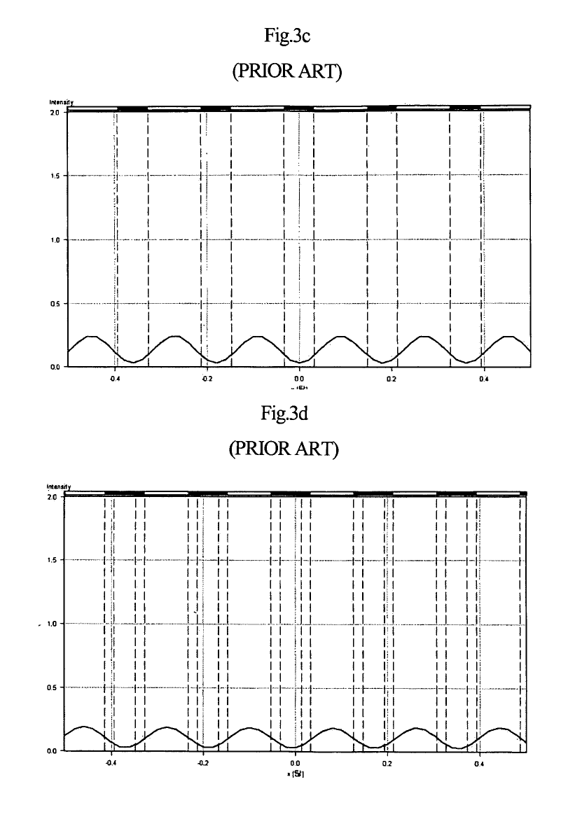

FIGS. 4a to 4c are a plan view, and vertical cross-sectional views illustrating a multi-transmission phase mask in accordance with one preferred embodiment of the invention, respectively, in which FIG. 4b is a vertical cross-sectional view taken along line A-A′ of FIG. 4a, and FIG. 4c is a vertical cross-sectional view taken along line B-B′ of FIG. 4a.

The multi-transmission phase mask in accordance with one embodiment of the invention comprises: a light transmissive substrate 100; a light shielding layer 102, such as a chrome film, formed on the light transmissive substrate 100 so as to prevent light from being transmitted therethrough and defining a plurality of pattern regions 104 of a semiconductor; and a phase shift region 106 formed between adjacent pattern regions 104 such that a predetermined portion of the light transmissive substrate 100 is exposed (for example, in a row direction) to the outside between the adjacent pattern regions 104.

In the multi-transmission phase mask of the invention, the pattern regions 104 of the semiconductor are formed by etching the light transmissive substrate 100 to a predetermined depth through the light shielding layer 102, and serve to provide a phase delay of 180°.

In the multi-transmission phase mask of the invention, the phase shift region 106 corresponds to a region of the light transmissive substrate 100 exposed to the outside between removed portions of the light shielding layer 102, and serves to provide a phase delay of 0°. At this time, the phase shift region 106 is formed between the pattern regions 104 of the semiconductor in the direction of the row.

Thus, in the multi-transmission phase mask of the present embodiment, since each of the pattern regions 104, such as storage node contacts and so forth, provides the phase delay of 180° for transmitted light and the phase shift region 106, formed on the gap in the row direction between the pattern regions, provides the phase delay of 0° for transmitted light, a phase difference of 180° is generated therebetween, thereby compensating for the optical proximity effect occurring in the minute gap between the pattern regions. At this time, an etching depth of the light transmissive substrate 100 must be controlled such that each of the pattern regions 104, such as the storage node contacts, provides the phase delay of 180°.

As such, when an exposure process is conducted by an exposure apparatus, such as a KrF exposure apparatus, using the multi-transmission phase mask of the present embodiment, the problem of an undesired pattern profile, such as storage node contacts, or inaccuracy in critical dimension of the pattern due to the optical proximity effect which occurs in the minute gap between the pattern regions can be solved by means of the phase shift region 106 providing a phase difference of 180° on the gap in the direction of the row between the pattern regions, such as storage node contacts and so forth.

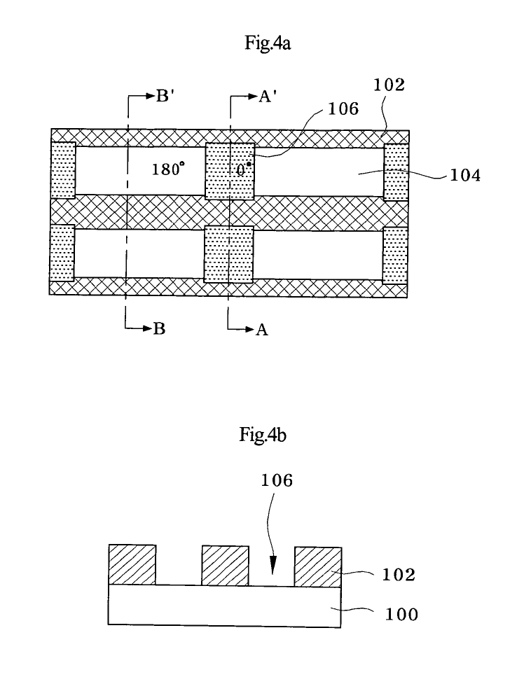

FIGS. 5a to 5c are a plan view, and vertical cross-sectional views respectively illustrating a multi-transmission phase mask in accordance with another preferred embodiment of the invention, in which FIG. 5b is a vertical cross-sectional view taken along line A-A′ of FIG. 5a, and FIG. 5c is a vertical cross-sectional view taken along line B-B′ of FIG. 5a.

The multi-transmission phase mask in accordance with another embodiment of the invention comprises: a light transmissive substrate 100; a light shielding layer 102, such as a chrome film, formed on the light transmissive substrate 100 so as to prevent light from being transmitted therethrough and defining a plurality of pattern regions 104 of a semiconductor; and a phase shift region 106 formed between adjacent pattern regions 104 such that a predetermined portion of the light transmissive substrate 100 is exposed (for example, in a column direction) to the outside between the adjacent pattern regions 104.

In the multi-transmission phase mask of the present embodiment, each of the pattern regions 104 of the semiconductor is formed by etching the light transmissive substrate 100 to a predetermined depth through the light shielding layer 102, and serves to provide a phase delay of 180°.

In the multi-transmission phase mask of the present embodiment, the phase shift region 106 corresponds to a region of the light transmissive substrate 100 exposed to the outside between removed portions of the light shielding layer 102, and serves to provide a phase delay of 0°. At this time, the phase shift region 106 is formed between the pattern regions 104 of the semiconductor in the column direction.

Thus, in the multi-transmission phase mask of the present embodiment, since each of the pattern regions 104, such as storage node contacts and so forth, provides a phase delay of 180° for transmitted light and the phase shift region 106, formed on the gap in the column direction between the pattern regions, provides a phase delay of 0° for transmitted light, a phase difference of 180° is generated therebetween, thereby compensating for the optical proximity effect occurring in the minute gap between the pattern regions. At this time, an etching depth of the light transmissive substrate 100 must be controlled such that each of the pattern regions 104, such as the storage node contacts, provides the phase delay of 180°.

As such, when an exposure process is conducted by an exposure apparatus, such as a KrF exposure apparatus, using the multi-transmission phase mask of the embodiment, the optical proximity effect occurring on the minute gap between the pattern regions is compensated for by the phase shift region providing the phase difference of 180° in the space in the direction of the column between the pattern regions, such as storage node contacts and so forth, thereby ensuring a precise pattern profile of the storage node contacts and a critical dimension of the pattern.

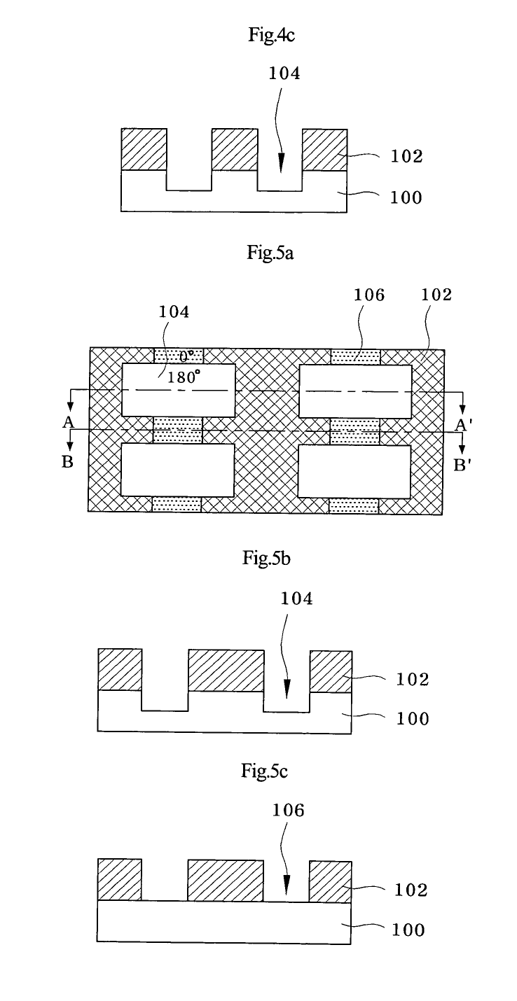

Referring to FIGS. 6a to 9b, a method of manufacturing a multi-transmission phase mask according to one embodiment of the invention will be described.

FIGS. 6a and 6b are diagrams illustrating a primary exposure process in the method of the invention, in which FIG. 6b is a vertical cross-sectional view taken along line C-C′ of FIG. 6a.

As shown in FIGS. 6a and 6b, a chrome film is formed as a light shielding layer 202 on a light transmissive substrate 200, for example, a glass substrate. Then, a photoresist 204 is formed on the light shielding layer 202, and the primary exposure process is performed using an electron-beam exposure apparatus to expose a plurality of regions of the photoresist, which will define a plurality of pattern regions on the multi-transmission phase mask.

A development process is performed on the photoresist 204 and 206 to remove only the exposed photoresist regions 206, thereby forming pattern regions of the photoresist 204, which becomes the pattern regions of the semiconductor, such as storage node contacts and so forth.

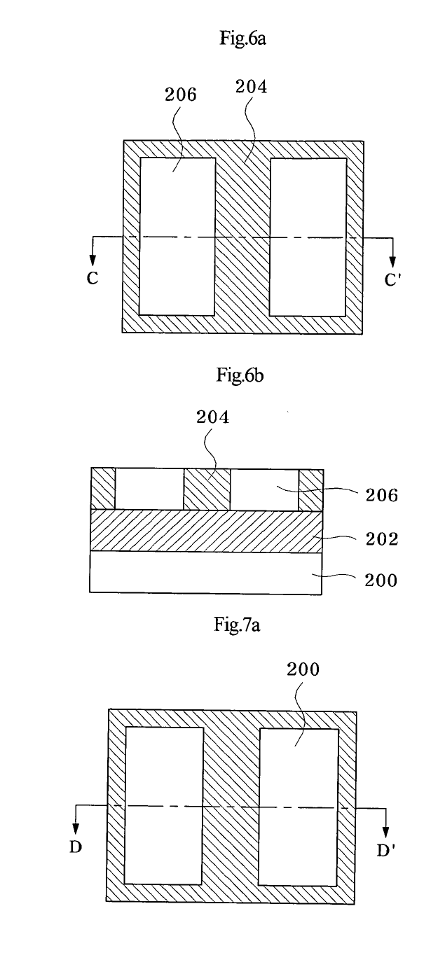

FIGS. 7a to 7c are diagrams illustrating a primary etching process in the method of the invention in which FIGS. 7b and 7c are vertical cross-sectional views taken along line D-D′ of FIG. 7a.

As shown in FIGS. 7a to 7c, a primary patterning process is performed on a plurality of regions of the light shielding layer 202 exposed to the outside between the pattern regions of the photoresist, which will define the pattern regions of the semiconductor. Accordingly, a plurality of light shielding layer patterns 202a are formed by the primary etching process using a plasma etching apparatus, and the light transmissive substrate 200 exposed to the outside between the light shielding layer patterns 202a is etched to a predetermined depth, thereby forming a plurality of pattern regions 207 of the semiconductor, which provides a phase delay of 180° for transmitted light. Then, the remaining photoresist is removed through a secondary plasma etching process.

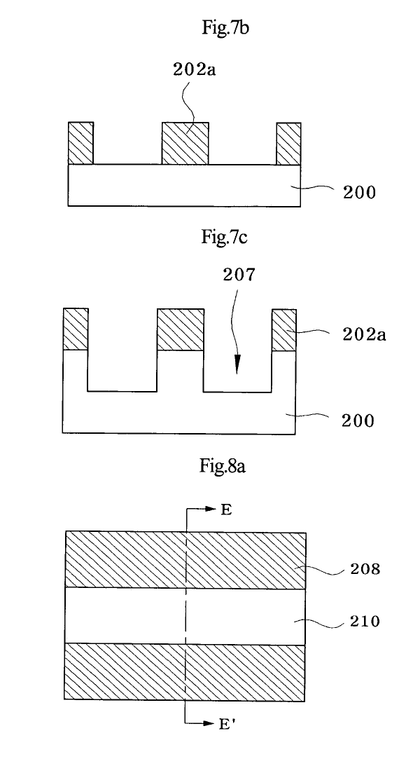

FIGS. 8a and 8b are diagrams illustrating a secondary exposure process in the method of the invention in which FIG. 8b is a vertical cross-sectional view taken along line E-E′ of FIG. 8a.

As shown in FIGS. 8a and 8b, after another photoresist 208 is formed on the primarily patterned light shielding layer 202a, the secondary exposure process is performed using the electron-beam exposure apparatus to expose a predetermined portion 210 of the photoresist 208, which will define the gap between the pattern regions of the multi-transmission phase mask. The gap between the pattern regions is formed in a line shape.

A development process is performed on the photoresist 208 and 210 to remove the exposed portion 210 of the photoresist 208, thereby forming a pattern of the remaining photoresist 208, in which the gap between the pattern regions of the semiconductor, such as the storage node contacts and so forth, is defined.

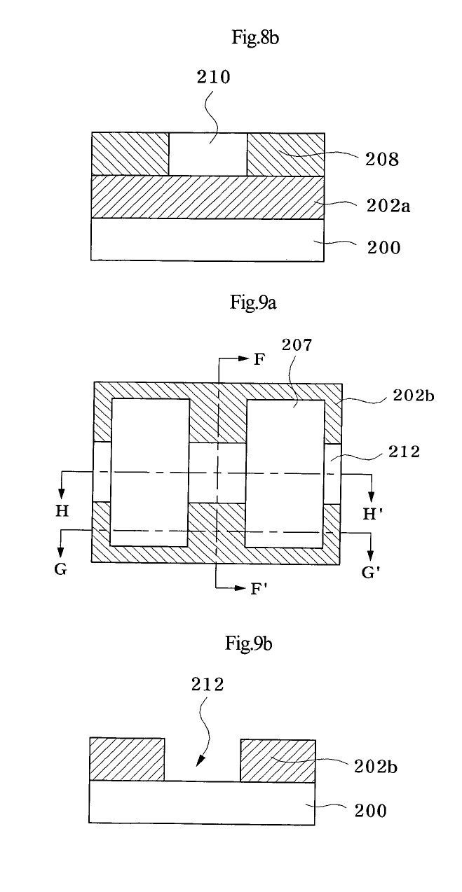

FIGS. 9a to 9d are diagrams illustrating a secondary etching process in the method of the invention in which FIGS. 9b to 9d are vertical cross-sectional views taken along lines F-F′, G-G′, and H-H′ of FIG. 9a.

As shown in FIGS. 9a to 9d, a secondary patterning process is performed to the light shielding layer pattern 202a exposed to the outside through the removed portion between the pattern regions of the photoresist, which defines the gap between the pattern regions of the semiconductor. Accordingly, a light shielding layer pattern 202b is etched by a secondary etching process using the plasma etching apparatus, thereby forming a phase shift region 212 with the surface of the light transmissive substrate 200 exposed through the light shielding layer pattern 202b. At this time, the phase shift region 212 provides the phase delay of 0° for the transmitted light, and corresponds to a gap in the direction of the row or column between the pattern regions 207 of the semiconductor. Then, the remaining photoresist is removed through a secondary plasma etching process.

In the method for manufacturing the multi-transmission phase mask according to the invention, the phase shift region 212 is formed after forming the pattern regions 207 of the semiconductor. Alternatively, when manufacturing the multi-transmission phase mask according to the invention, the phase shift region 212 may be formed through the processes of FIGS. 8a to 9d, before forming the pattern regions 207 of the semiconductor 207 through the processes of FIGS. 6a to 7b.

In the multi-transmission phase mask of the invention manufactured by the method as described above, since the pattern regions 207 of the semiconductor, such as the storage node contacts and so forth, provides the phase delay of 180° for the transmitted light and the phase shift region 212 between the pattern regions 207 provides the phase delay of 0° for the transmitted light, a phase difference of 180° is generated in these regions, thereby compensating for the optical proximity effect occurring in the minute gap between the pattern regions. At this time, an etching depth of the light transmissive substrate 100 must be controlled such that the pattern regions 104, such as storage node contacts, provide the phase delay of 180°.

Additionally, in the method for manufacturing the multi-transmission phase mask of the invention, since the pattern regions 207 of the semiconductor and the phase shift region 212 providing the phase difference of 180° therebetween are formed through the two exposure processes and the patterning (etching) process, a correct overlay of the pattern region and the gap, which provide the phase difference of 180°, can be provided.

Meanwhile, a modified illumination system having at least two open poles, each having a preset opening angle, is employed during the exposure process as shown in FIGS. 6a and 8a. At this time, the number of open poles, opening angles of the open poles, and a direction of the opening angle in the modified illumination system are determined according to locations of the phase shift region in the multi-transmission phase mask.

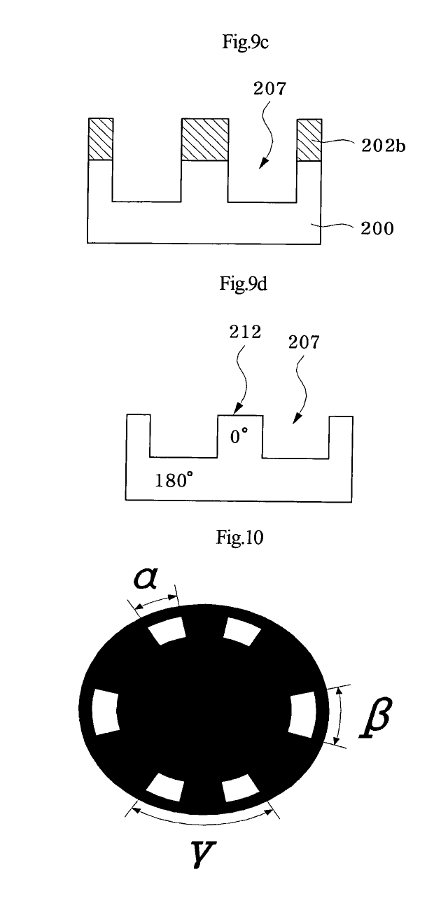

FIG. 10 shows one example of a modified illumination system used for the invention. The modified illumination system as shown in FIG. 10 is a modified illumination system having a hexapole, in which each pole of the hexapole has, for example, an opening angle α of 15° to a vertical axis, an opening angle β of 15° to a horizontal axis, and an opening angle γ of 60° defined by a pair of poles.

Thus, according to the invention, the exposure process is performed while adjusting an optical transmittance and a phase of the multi-transmission phase mask with the modified illumination system having the hexapole.

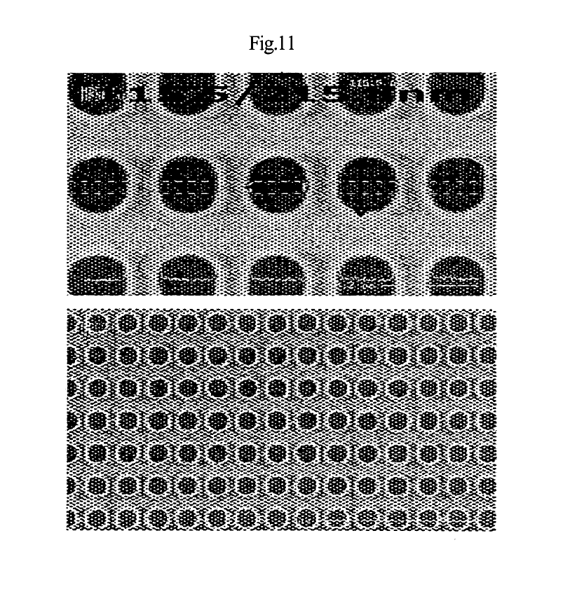

FIG. 11 shows a pattern of storage node contacts exposed on a wafer when the exposure process is performed using the multi-transmission phase mask of the invention and the modified illumination system.

When the exposure process is performed on a wafer by means of a 0.80NA KrF exposure apparatus using the modified illumination system as shown in FIG. 10 and the multi-transmission phase mask with the storage node contact having a half pitch of 95 nm as shown in FIG. 5a, an image of a uniform storage node contact pattern as shown in FIG. 11 is formed on the wafer by the exposure process. At this time, a depth of focus (DOF) is 0.5 μm, and the exposure limit (EL) is 12.7% upon the exposure process.

Meanwhile, although the pattern of the semiconductor, such as the storage node contacts and so forth, of the multi-transmission phase mask is described as having a rectangular pattern in the embodiment as described above, it is apparent to one skilled in the art that various modifications, such as the addition of an assistant pattern region to the above pattern region, change in shape of the pattern, and adjustment of the location of the phase shift region, are also allowed. Moreover, the light transmissive substrate and the light shielding layer may also be made of other materials such that a predetermined phase difference is generated between the pattern region of the semiconductor and the gap of the pattern regions.

As apparent from the above description, according to the present invention, each of the pattern regions provides the phase delay of 180°, and the gap between the pattern regions provides the phase delay of 0° by means of the light shielding layer formed on the light transmissive substrate and the phase shift region formed by etching the light transmissive substrate to the predetermined depth, so that the phase difference of 180° is generated therebetween, thereby realizing a minute and repetitious pattern profile of the semiconductor, such as storage node contacts, and a critical dimension of the pattern with high precision.

Furthermore, according to the present invention, the pattern region having a phase of 180° is formed by the primary patterning process, and the gap having a phase of 0° is formed by the secondary patterning process, so that overlay of the pattern region and the space in the pattern region providing the phase difference can be matched, thereby realizing a minute and repetitious pattern profile of the semiconductor, such as a storage node contact pattern, and a critical dimension of the pattern with high precision.

It should be understood that the embodiments and the accompanying drawings have been described for illustrative purposes and the present invention is limited by the following claims. Further, those skilled in the art will appreciate that various modifications, additions and substitutions are allowed without departing from the scope and spirit of the invention as set forth in the accompanying claims.

What is claimed is:

1. A multi-transmission phase mask used for an exposure apparatus, comprising:
a light transmissive substrate of the mask;
a light shielding layer formed on the light transmissive substrate so as to prevent light from being transmitted therethrough and defining a plurality of pattern regions of a semiconductor; and
a phase shift region formed between adjacent pattern regions such that a predetermined portion of a surface of the light transmissive substrate between the adjacent pattern regions of the semiconductor is exposed to the outside, the pattern region of the semiconductor being formed by etching the light transmissive substrate to a predetermined depth through the light shielding layer.

2. The mask according to claim 1, wherein the phase shift region has a phase difference of 180° to the pattern region.

3. The mask according to claim 1, wherein the phase shift region is formed in the direction of the row between the adjacent patterned regions.

4. The mask according to claim 1, wherein the phase shift region is formed in the direction of the column between the adjacent patterned regions.

5. The mask according to claim 1, wherein each of the pattern regions comprises an assistant pattern region.

6. A method of manufacturing a multi-transmission phase mask used for an exposure apparatus, comprising the steps of:
first patterning a light shielding layer after forming the light shielding layer on a light transmissive substrate;
forming a plurality of pattern regions of a semiconductor by etching the light transmissive substrate to a predetermined depth using the first patterned light shielding layer; and
secondarily patterning the light shielding layer and forming a phase shift region between adjacent pattern regions of the semiconductor such that a predetermined portion of a surface of the light transmissive substrate is exposed to the outside between the adjacent pattern regions of the semiconductor.

7. The method according to claim 6, wherein the phase shift region has a phase difference of 180° to the pattern region.

8. The method according to claim 6, wherein the phase shift region is formed in the direction of the row between the adjacent patterned regions.

9. The method according to claim 6, wherein the phase shift region is formed in the direction of the column between the adjacent patterned regions.

10. The method according to claim 6, wherein the primarily patterning of the light shielding layer comprises an exposure process and an etching process using a modified illumination system having at least two poles, each having a preset opening angle.

11. The method according to claim 6, wherein the secondarily patterning of the light shielding layer comprises an exposure process and an etching process using a modified illumination system having at least two poles, each having a preset opening angle.
